(19) United States
(12) Patent Application Publication
(10) Pub. No.: US 2022/0093371 A1
(43) Pub. Date: Mar. 24, 2022

(54) RADIATION SHIELD FOR REMOVING BACKSIDE DEPOSITION AT LIFT PIN LOCATIONS

(71) Applicant: Applied Materials, Inc., Santa Clara, CA (US)

(72) Inventors: Zubin Huang, Santa Clara, CA (US); Truong Van Nguyen, Milpitas, CA (US); Rui Cheng, San Jose, CA (US); Diwakar Kedlaya, San Jose, CA (US); Manjunath Veerappa Chobari Patil, Bengaluru (IN); Prashant A. Desai, Bangalore (IN); Paul L. Brillhart, Pleasanton, CA (US); Karthik Janakiraman, San Jose, CA (US); Pavan Kumar Murali Kumar, Bangalore (IN)

(73) Assignee: Applied Materials, Inc., Santa Clara, CA (US)

(21) Appl. No.: 17/026,885

(22) Filed: Sep. 21, 2020

(51) Int. Cl. H01J 37/32; C23C 16/455; C23C 16/458; C23C 16/44

(52) U.S. Cl. CPC H01J 37/32651; H01J 37/32477; H01J 37/32633; C23C 16/4408; C23C 16/45591; C23C 16/4585; H01J 37/32715

(57) ABSTRACT

Exemplary semiconductor processing systems include a chamber body having sidewalls and a base. The systems may include a substrate support extending through the base. The substrate support may include a support plate defining lift pin locations and a shaft coupled with the support plate. The systems may include a shield coupled with the shaft and extending below the support plate. The shield may define a central aperture that extends beyond an outer periphery of the shaft. The systems may include a purge baffle coupled with the shield at a position that is beyond the central aperture such that a space between the purge baffle and the shaft is in fluid communication with a space between the shield and the support plate. The purge baffle may extend along at least a portion of the shaft. The systems may include a purge gas source coupled with the purge baffle.

### TECHNICAL FIELD

The present technology relates to components and apparatuses for semiconductor manufacturing. More specifically, the present technology relates to processing chamber components and other semiconductor processing equipment.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### SUMMARY

Exemplary semiconductor processing systems may include a chamber body including sidewalls and a base. The systems may include a substrate support extending through the base of the chamber body. The substrate support may include a support plate that defines a plurality of lift pin locations. The substrate support may include a shaft coupled with the support plate. The systems may include a shield coupled with the shaft of the substrate support and that extends below a bottom surface of the support plate. The shield may define a central aperture that extends beyond an outer periphery of the shaft. The systems may include a purge baffle coupled with a bottom of the shield at a position that is beyond an outer periphery of the central aperture such that a space between the purge baffle and the outer periphery of the shaft is in fluid communication with a space between a top surface of the shield and the bottom surface of the support plate. The purge baffle may extend along at least a portion of a length of the shaft. The systems may include a purge gas source coupled with a bottom of the purge baffle.

In some embodiments, a peripheral edge of the shield may be positioned radially inward from the plurality of lift pin locations of the support plate. A peripheral edge of the shield may be positioned radially outward from the plurality of lift pin locations of the support plate. The shield may define a plurality of apertures that extend at least partially through a thickness of the shield. Each of the plurality of apertures may be aligned with one of the plurality of lift pin locations. The shield may define one or more grooves that extend between the central aperture and the plurality of lift pin locations. A depth of the one or more grooves may vary along a length of the one or more grooves. The depth of the one or more grooves may decrease in a radially outward direction. The shield may include a texture that provides an emissivity pattern for temperature modulation of a semiconductor substrate positioned atop the support plate.

Some embodiments of the present technology may encompass semiconductor processing systems. The systems may include a substrate support. The substrate support may include a support plate defining a plurality of lift pin locations. The substrate support may include a shaft coupled with the support plate. The systems may include a shield having a body that defines a central aperture. The systems may include a purge baffle coupled with a bottom of the shield at a position that is beyond an outer periphery of the central aperture. The purge baffle may extend along at least a portion of a length of the shaft. A purge gas channel may be formed in a space between the purge baffle, the shield, and the substrate support. The systems may include a purge gas source coupled with a bottom of the purge baffle.

In some embodiments, a peripheral edge of the shield may be positioned radially inward from the plurality of lift pin locations of the support plate. A peripheral edge of the shield may be positioned radially outward from the lift pin locations of the support plate. The shield may define a plurality of apertures that extend at least partially through a thickness of the shield. Each of the plurality of apertures may be aligned with one of the plurality of lift pin locations. The shield may define one or more grooves that extend between the central aperture and the plurality of lift pin locations. A depth of the one or more grooves may vary along a length of the one or more grooves. The depth of the one or more grooves may decrease in a radially outward direction. The shield may include a texture that provides an emissivity pattern for temperature modulation of a semiconductor substrate positioned atop the support plate.

Some embodiments of the present technology may encompass methods of semiconductor processing. The methods may include flowing a purge gas into a processing chamber. The processing chamber may include a substrate support. The substrate support may include a support plate that supports a semiconductor substrate. The substrate support may include a shaft coupled with the support plate. The chamber may include a shield having a body that defines a central aperture. The chamber may include a purge baffle coupled with a bottom of the shield at a position that is outside of the central aperture. The purge baffle may extend along at least a portion of a length of the shaft. A purge gas channel may be formed in a space between the purge baffle, the shield, and the substrate support. The chamber may include a purge gas source coupled with a bottom of the purge baffle. The methods may include delivering the purge gas to an underside of the semiconductor substrate at positions that are aligned with the plurality of lift pin locations via the purge gas channel.

In some embodiments, delivering the purge gas to the underside of the semiconductor substrate may include passing the purge gas through one or more grooves that extend outward from the central aperture to the plurality of lift pin locations. A depth of the one or more grooves may vary along a length of the one or more grooves. The depth of the one or more grooves may decrease in a radially outward direction. A peripheral edge of the shield may be positioned radially inward from the lift pin locations of the support plate. Delivering the purge gas to the lift pin locations via the purge gas channel may include passing the purge gas beyond the peripheral edge of the shield. The purge baffle may be positioned about and spaced apart from an outer surface of the shaft and extends along at least a portion of the length of the shaft.

Such technology may provide numerous benefits over conventional systems and techniques. For example, embodiments of the present technology may deliver purge gas to the backside of a semiconductor substrate to remove any deposition on the substrate at lift pin locations. Additionally, the components may allow modification to accommodate any number of chambers or processes. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing chamber according to some embodiments of the present technology.

FIG. 4 shows a schematic bottom plan view of chamber components according to some embodiments of the present technology.

FIG. 5 shows a schematic bottom plan view of chamber components according to some embodiments of the present technology.

FIGS. 6A-6D show schematic top plan views of exemplary shields according to some embodiments of the present technology.

FIG. 6E shows a schematic cross-sectional view of the shield of FIG. 6D according to some embodiments of the present technology.

FIG. 7A-7C show schematic top plan views of exemplary shield emissivity patterns according to some embodiments of the present technology.

FIG. 8 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

Oftentimes, the delivery of precursors is done with high pressures within the processing chamber. The high chamber pressure forces deposition gases to flow to the backside of a substrate support, and then up to a backside of the substrate via holes formed within the pedestal that are designed to provide access for lift pins. As the deposition gases are forced through the lift pin holes, effluent materials are deposited on the backside of the substrate, which may cause particle and defect issues on the substrate.

The present technology overcomes these challenges by utilizing a purge shield and purge baffle that may be used to direct purge gas to the backside of the substrate at the lift pin locations. The purge gas may then remove any deposition formed on the backside of the substrate at these locations. Accordingly, the present technology may produce improved film deposition characterized by fewer defects associated with backside gas deposition.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

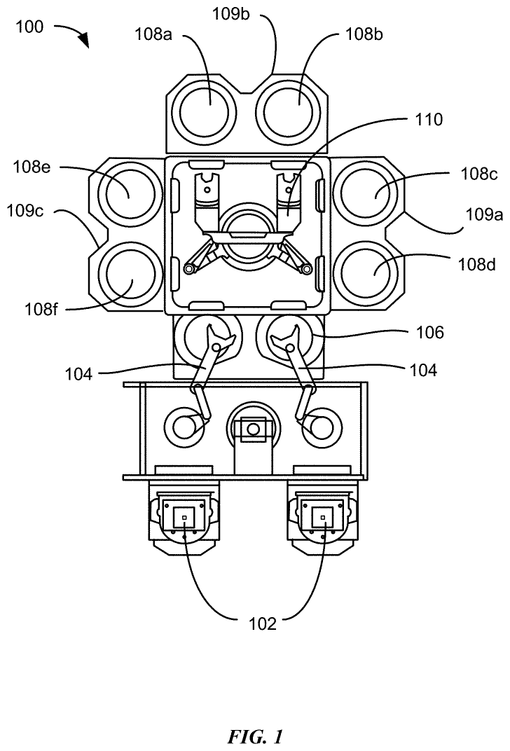

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

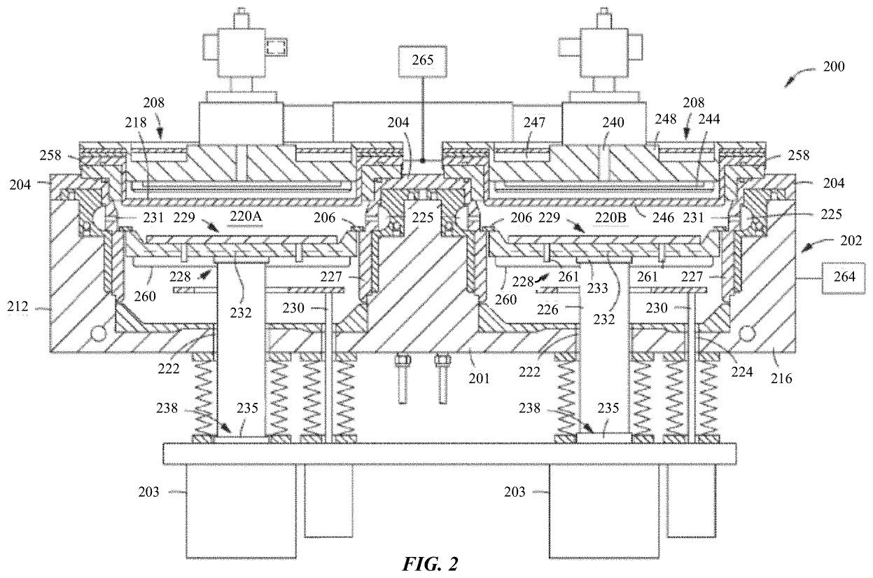

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

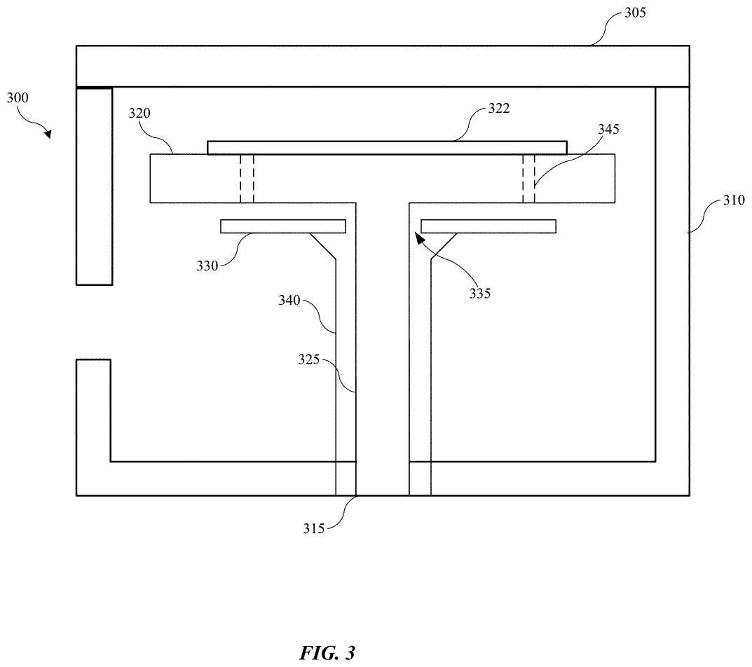

FIG. 3 shows a schematic partial cross-sectional view of an exemplary processing system 300 according to some embodiments of the present technology. FIG. 3 may illustrate further details relating to components in system 200, such as for pedestal 228. System 300 is understood to include any feature or aspect of system 200 discussed previously in some embodiments. The system 300 may be used to perform semiconductor processing operations including deposition of hardmask materials as previously described, as well as other deposition, removal, and cleaning operations. System 300 may show a partial view of the chamber components being discussed and that may be incorporated in a semiconductor processing system, and may illustrate a view without several of the lid stack components noted above. Any aspect of system 300 may also be incorporated with other processing chambers or systems as will be readily understood by the skilled artisan.

System 300 may include a processing chamber including a faceplate 305, through which precursors may be delivered for processing, and which may be coupled with a power source for generating a plasma within the processing region of the chamber. The chamber may also include a chamber body 310, which as illustrated may include sidewalls and a base. A pedestal or substrate support 315 may extend through the base of the chamber as previously discussed. The substrate support may include a support plate 320, which may support semiconductor substrate 322. The support plate 320 may define a number of lift pin locations 345. Lift pin locations 345 may be in the form of apertures that extend through a thickness of the support plate 320 which enable substrate lift pins to be positioned beneath the substrate 322 to selectively space the substrate from the support plate 320 to facilitate exchange of the substrate 332 with a robot utilized for transferring the substrate 322 into and out of a processing region of the processing chamber. Oftentimes, the lift pin locations 345 may be uniformly arranged about the support plate 320. For example, three lift pin locations 345 may be disposed at regular angular intervals of 120 degrees relative to a center of the support plate 320. In other embodiments, some or all of the lift pin locations 345 may be arranged at irregular intervals. The number of lift pin locations 345 may vary. For example, the support plate 320 may define greater than or about 3 lift pin locations 345, greater than or about 4 lift pin locations 345, greater than or about 5 lift pin locations 345, greater than or about 6 lift pin locations 345, greater than or about 7 lift pin locations 345, or more. Each of the lift pin locations 345 may be positioned at a same radial distance from the center of the support plate 320. For example, each lift pin location 345 may be positioned at locations that are proximate edges of substrate 322. In embodiments in which a support plate 320 may be used to support substrates 322 of various sizes, multiple sets of lift pin locations 345 at different radial distances may be used or a single set of lift pin locations 345 may be positioned at a radial distance to accommodate a smallest size of substrate 322. In some embodiments, some or all of the lift pin locations 345 may be at different radial distances as at least one other lift pin location 345.

The support plate 320 may be coupled with a shaft 325, which may extend through the base of the chamber. System 300 may also incorporate a shield 330, which may be coupled about or with the shaft 325 of the substrate support 315. The shield 330 may define a central aperture 335 through which the shaft 325 may extend. The central aperture 335 may have a diameter that is greater than a diameter or thickness of the shaft 325 so as to provide a fluid channel between an outer surface of the shaft 325 and an outer periphery of the central aperture 335. A bottom of the shield 330 may be coupled with a purge baffle 340, with the purge baffle 340 being positioned outside of the central aperture 335. The purge baffle 340 may extend along at least a portion of the length of the shaft 325 and may be spaced apart from the outer surface of the shaft 325. A bottom end purge baffle 340 may be coupled with a purge gas source.

Gas from the purge gas source may be flowed into a space between the outer surface of the shaft 325 and an interior surface of the purge baffle 340 and up through the central aperture 335 into a space between a top surface of the shield 330 and a bottom surface of the support plate 320. For example, the purge gas source may flow a purge gas such as, but not limited to, argon, helium, and/or hydrogen, upward through the purge baffle 340. The purge gas may be flowed at various flow rates based on various factors, such as the amount of purge gas needed to remove deposition at the lift pin locations 345, the number of lift pin locations 345, a distance between the shield 330 and a bottom surface of the support plate 320, and/or a design of shield 330. For example, purge gas may be flowed from the purge gas source at rates of greater than or about 100 sccm, greater than or about 200 sccm, greater than or about 300 sccm, greater than or about 400 sccm, greater than or about 500 sccm, greater than or about 600 sccm, greater than or about 700 sccm, greater than or about 800 sccm, greater than or about 900 sccm, greater than or about 1 liter per minute, greater than or about 2 liters per minute, greater than or about 3 liters per minute or more, although higher or lower flow rates may be used. The shield 330 may then direct the purge gas to flow outward toward the lift pin locations 345, enabling the purge gas to remove any deposition formed on the backside of the substrate 322 at the lift pin locations 345. In some embodiments, the shield 330 may also serve as a heat shield and/or radiation shield.

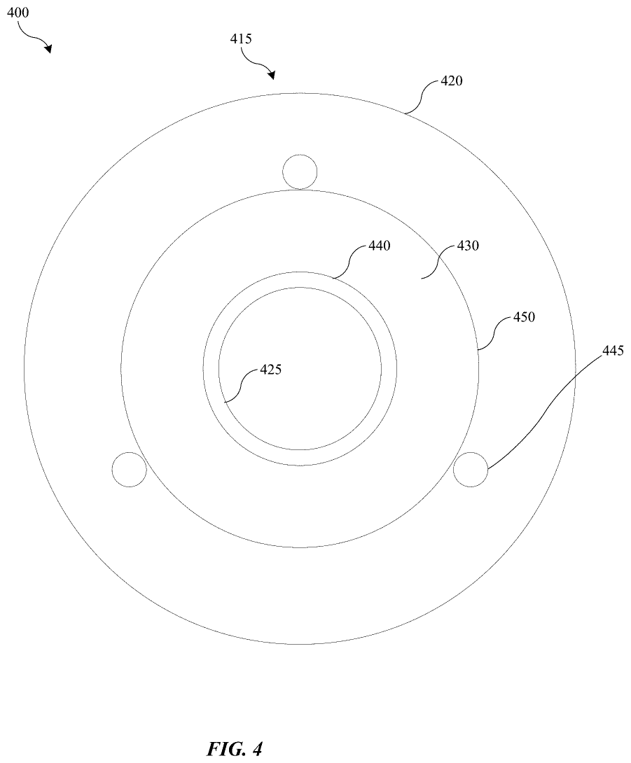

FIG. 4 shows a schematic partial bottom plan view of a processing chamber 400 according to some embodiments of the present technology. FIG. 4 may include one or more components discussed above with regard to FIGS. 2 and 3, and may illustrate further details relating to that chamber. Chamber 400 is understood to include any feature or aspect of system 200 and/or system 300 discussed previously. Chamber 400 may show a partial view of a processing region of a semiconductor processing system, and may not include all of the components, and which are understood to be incorporated in some embodiments of chamber 400. Chamber 400 may include a substrate support 415 that includes a support plate 420. The support plate 420 may define a number of lift pin locations 445 in the form of apertures that extend through a thickness of the support plate 420. The substrate support 415 may also include a shaft 425 which may extend through the base of the chamber 400. Chamber 400 may also include a purge baffle 440 that is disposed about the shaft 425, with an inner surface of the purge baffle 440 being spaced apart from an outer surface of the shaft 425 to form a purge gas channel. Chamber 400 may include a shield 430, which may be positioned beneath the support plate 420. Purge gas may be flowed from a purge gas source through the purge channel and into a space between the shield 430 and bottom surface of the support plate 420. The shield 430 may direct the purge gas radially outward to the lift pin locations 445. For example, a peripheral edge 450 of the shield 430 may be positioned radially inward from the lift pin locations 445, which forces purge gas introduced via the purge gas channel to flow outward to the lift pin locations 445 while also ensuring that lift pins may be insertable within the apertures of the lift pin locations 445.

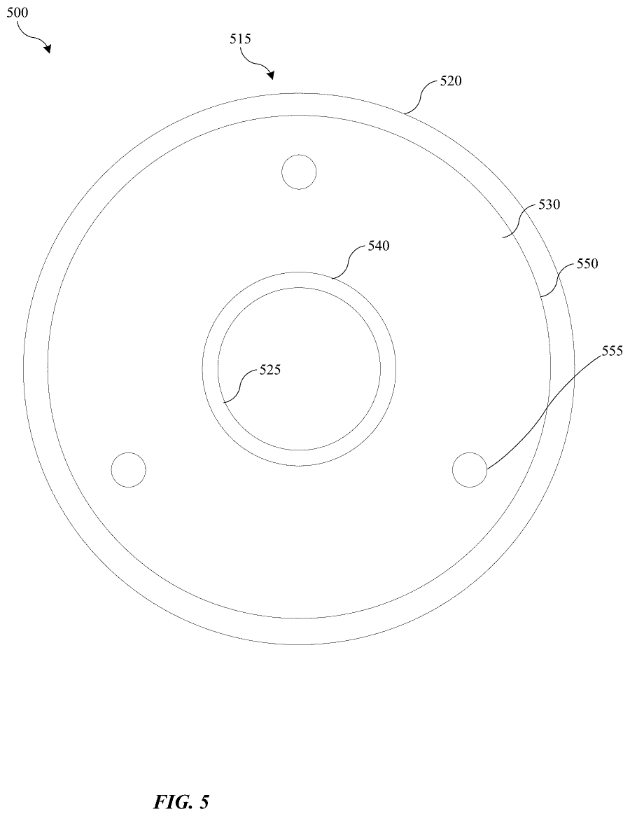

FIG. 5 shows a schematic partial bottom plan view of a processing chamber 500 according to some embodiments of the present technology. FIG. 5 may include one or more components discussed above with regard to FIGS. 2 and 3, and may illustrate further details relating to that chamber. Chamber 500 is understood to include any feature or aspect of system 200 and/or system 300 discussed previously. Chamber 500 may show a partial view of a processing region of a semiconductor processing system, and may not include all of the components, and which are understood to be incorporated in some embodiments of chamber 500. Chamber 500 may include a substrate support 515 that includes a support plate 520. The support plate 520 may define a number of lift pin locations (not shown) in the form of apertures that extend through a thickness of the support plate 420. The substrate support 415 may also include a shaft 525 which may extend through the base of the chamber 500. Chamber 500 may also include a purge baffle 540 that is disposed about the shaft 525, with an inner surface of the purge baffle 540 being spaced apart from an outer surface of the shaft 525 to form a purge gas channel. Chamber 500 may include a shield 530, which may be positioned beneath the support plate 520. Purge gas may be flowed from a purge gas source through the purge channel and into a space between a top surface of the shield 530 and bottom surface of the support plate 520. A peripheral edge 550 of the shield 530 may be positioned radially outward from the lift pin locations such that the purge gas introduced via the purge gas channel is forced outward to the lift pin locations. The purge gas may remove any deposition that has occurred on a backside of a substrate at the lift pin locations.

The shield 530 may define a number of apertures 555 that extend through a thickness of the shield 530. The apertures 555 may be aligned with the lift pin locations to enable lift pins to be inserted through the apertures 555 and into the lift pin locations to manipulate a substrate positioned atop the support plate 520. For example, the apertures 555 may be arranged to match positions of at least some of the lift pin locations of the support plate 520. A diameter of each aperture 555 may be approximately the same size or greater than a size of the apertures of the lift pin locations. The apertures 555 may be uniformly arranged about the shield 530. For example, three apertures 555 may be disposed at regular angular intervals of 120 degrees relative to a center of the shield 530. In other embodiments, some or all of the apertures 555 may be arranged at irregular intervals. The number of apertures 555 may vary. For example, the shield 530 may define greater than or about 3 apertures 555, greater than or about 4 apertures 555, greater than or about 5 apertures 555, greater than or about 6 apertures 555, greater than or about 7 apertures 555, or more. Each of the apertures 555 may be positioned at a same radial distance from the center of the shield 530. In some embodiments, multiple sets of apertures 555 at different radial distances may be included. In some embodiments, some or all of the apertures 555 may be at different radial distances as at least one other aperture 555.

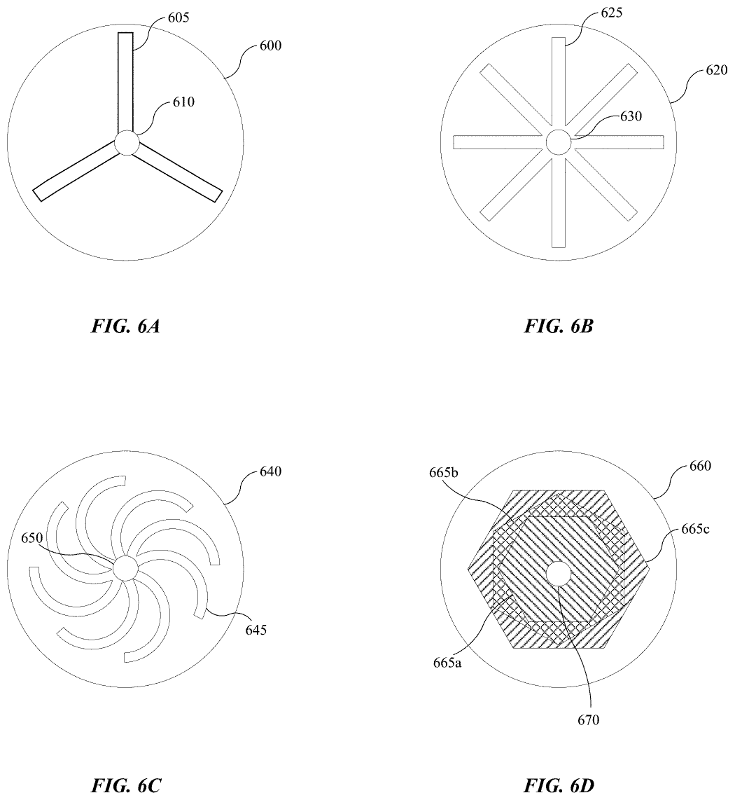

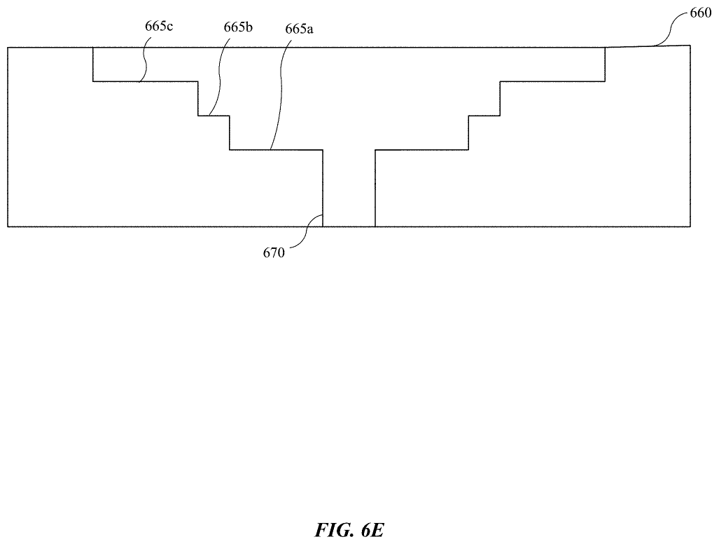

FIGS. 6A-6D show schematic top plan views of exemplary shields according to some embodiments of the present technology. The shields may be included in any chamber or system previously described, as well as any other chamber or system that may benefit from the shielding. The top surfaces of each shield may be utilized with the shields 430 and 530 described in FIGS. 4 and 5. The top surface of the shields may include one or more grooves that serve as flow channels that provide various flow patterns for efficient purge flow. The grooves may have various cross-sectional shapes, such as rectangular grooves with sharp bottom corners, rectangular grooves with rounded corners, U-shaped grooves, V-shaped grooves, and/or other cross-sectional shapes. The shield may be positioned against a bottom surface of a support plate with a top of the grooves being closed by the bottom surface of the support plate. In other embodiments, the shield may be spaced apart from the bottom surface of the support plate. For example, the shield may be spaced apart from the bottom surface of the support plate by a distance of between about 0.5 mm and 30 mm. The shield may be formed from a number of materials, and in some embodiments may be or include metallic and/or ceramic materials.

As illustrated in FIG. 6A, a shield 600 includes a number of radial grooves 605. Each of the grooves 605 is fluidly coupled with a central aperture 610. Purge gas may be flowed through the central aperture 610 and through the grooves 605 which direct the purge gas outward toward lift pin locations of a support plate. The grooves 605 may be positioned to intersect with the lift pin locations. For example, for a support plate having three lift pin locations spaced apart at equal angles, three grooves 605 may extend outward from the central aperture 610 at 120 degrees relative to one another in alignment with the lift pin locations. The grooves 605 may extend from the central aperture 610 to a position that approximately matches the lift pin locations. In other embodiments, the grooves 605 may extend partially to the lift pin locations or extend beyond the lift pin locations. Each groove 605 may have the same depth, width, shape, and/or length as the other grooves 605. In other embodiments, one or more of the grooves 605 may have a different depth, width, shape, and/or length than at least one of the other grooves 605. For example, in embodiments in which a support plate has lift pin locations that are irregularly spaced relative to one another, an arrangement of grooves 605 having various depths, widths, shapes, and/or lengths may be utilized to provide efficient purge gas flow to each lift pin location. While shown with three grooves 605, shield 600 may include any number of grooves 605. For example, the shield 600 may have greater than or about one groove, greater than or about two grooves, greater than or about 3 grooves, greater than or about 4 grooves, greater than or about 5 grooves, greater than or about 6 grooves, greater than or about 7 grooves, greater than or about 8 grooves, or more. FIG. 6B illustrates another embodiment of a shield 620 having radial grooves 625. Shield 620 may be similar to shield 600 and may include a central aperture 630 that enables purge gas to be flowed through a thickness of the shield 620 and into the grooves 625. As illustrated, the shield 620 includes eight radial grooves extending outward from the central aperture 630 at regular angular intervals. While FIGS. 6A and 6B illustrate shields with grooves arranged at regular angular intervals, it will be appreciated that some embodiments may include grooves arranged at irregular intervals about a surface of the shield.

FIG. 6C illustrates a shield 640 having a number of arcuate grooves 645 that extend outward from a central aperture 650. For example, the grooves 645 may be arranged in a spiral pattern about a top surface of the shield 640. The arcuate grooves 645 may have a constant circular arc shape and/or may have an arc shape having a curvature that varies along a length of each respective groove 645. The grooves 645 may be positioned such that at least a portion of one or more of the grooves 645 intersect with the lift pin locations of a support plate. For example, a distal portion of each of the grooves 645 may terminate at one of the lift pin locations. In other embodiments, the grooves 645 may extend partially to the lift pin locations or extend beyond the lift pin locations. Each groove 645 may have the same or different depth, width, shape, and/or length as at least one of the other grooves 645. While shown with eight arcuate grooves 645, shield 640 may include any number of grooves 645. For example, the shield 640 may have greater than or about one groove, greater than or about two grooves, greater than or about 3 grooves, greater than or about 4 grooves, greater than or about 5 grooves, greater than or about 6 grooves, greater than or about 7 grooves, greater than or about 8 grooves, or more. The arcuate grooves 645 may be disposed at regular and/or irregular intervals relative to one another to efficiently direct purge gas to the lift pin locations of a particular support plate.

FIG. 6D illustrates a shield 660 having a number of regular hexagonal grooves 665 extending into a top surface of the shield 660. For example, three hexagonal grooves 665 of different sizes may be coaxial with one another in a nested arrangement. The center of each groove 665 may also be coaxial with a central aperture 670 that enables purge gas to be flowed upward through a thickness of the shield 660 and into the grooves 665, where the purge gas is diffused toward lift pin locations of a support plate. FIG. 6E illustrates a schematic cross-sectional view of shield 660. Each of the grooves 665 may have a different depth. For example, a groove depth may decrease in an outward direction as the grooves extend from the central aperture 670, with an innermost groove 665a being deepest, an intermediate groove 665b being at an intermediate depth, and an outermost groove 665c being shallowest. In other embodiments, the groove depth may increase in an outward direction and/or may both increase and decrease in an outward direction at different groove positions. The groove depths may change in a stepped fashion, with transition points defined by generally vertical walls. In other embodiments, transitions between different depths of grooves 665 may include tapered and/or curved walls that connect the various grooves 665. In other embodiments, some or all of a bottom of the grooved area may be tapered and/or curved to provide a constant or variable taper along a radial length of each groove 665.

Turning back to FIG. 6D, each hexagonal groove 665 may be oriented differently than an adjacent hexagonal groove 665. For example, each of the hexagonal grooves 665 may be rotated at a particular angle, such as 30 degrees, relative to one another. The grooves 665 may be sized and positioned such that at least a portion of one or more of the grooves 665 intersect with the lift pin locations of a support plate. For example, a distal portion of the outermost groove 665 may terminate at one of the lift pin locations. In other embodiments, the outermost groove 665 may extend partially to the lift pin locations or extend beyond the lift pin locations. While shown with three hexagonal grooves 665, shield 660 may include any number of grooves 665. For example, the shield 660 may have greater than or about one groove, greater than or about two grooves, greater than or about 3 grooves, greater than or about 4 grooves, greater than or about 5 grooves, greater than or about 6 grooves, greater than or about 7 grooves, greater than or about 8 grooves, or more. In some embodiments, the grooves 665 may have other shapes, such as triangles, rectangles, pentagons, octagons, diamonds, circles, ellipses, other polygons, and/or other shapes. The groove shapes may be regular and/or irregular shapes. Additionally, while shown with each groove 665 being the same shape, some embodiments may include grooves of different shapes on a single shield 660.

It will be appreciated that shields having other shapes, numbers, and/or arrangement of grooves is possible in various embodiments. Some or all of the grooves may have constant depths and/or may have a depth that varies along a length of the respective groove. Shallower depths may provide increased purge gas velocity relative to deeper groove depths. Additionally, while shown with the grooves terminating at positions inward of a peripheral edge of each respective shield, it will be appreciated that in some embodiments, one or more of the grooves may extend through the peripheral edge of the respective shield. In some embodiments, the shields illustrated in FIGS. 6A-6D may have outer peripheries that are radially inward of lift pin positions of a support plate. In other embodiments, the shields may have outer peripheries that extend radially outward beyond the lift pin locations. In such embodiments, the shields may include apertures are aligned with the lift pin locations and that extend through a thickness of the shield. These apertures may provide access for lift pins to be inserted within the lift pin locations to manipulate a substrate positioned atop the support plate.

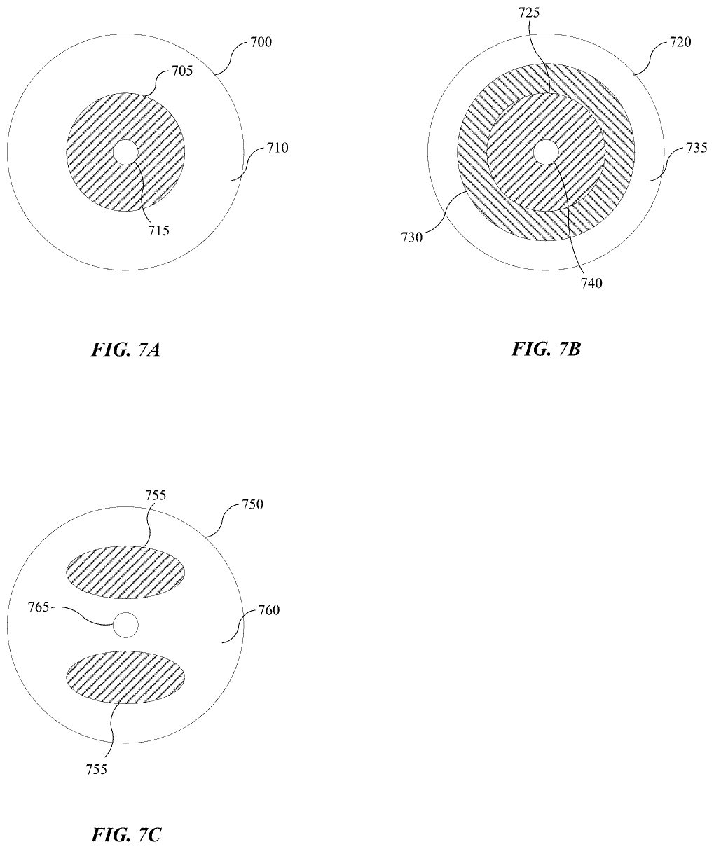

FIGS. 7A-7C show schematic top plan views of exemplary shields according to some embodiments of the present technology. The shields may be included in any chamber or system previously described, as well as any other chamber or system that may benefit from the shielding. The shields may be utilized as shields 430 and 530 described in FIGS. 4 and 5 and/or may incorporate grooves such as described in FIGS. 6A-6E. In some embodiments, some carbon-film deposition may be performed at temperatures above 600° C., or higher, which may facilitate adsorption of carbon radicals on a surface of the substrate. To maintain these processing temperatures, the substrate support, such as substrate support 315 of FIG. 3, may include one or more heating elements, which may be enabled to produce substrate or plate temperatures that may be greater than or about 500° C., and may be greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., greater than or about 750° C., greater than or about 775° C., greater than or about 800° C., or higher. While the substrate and aspects of the support may be maintained at higher temperatures, the chamber body may be maintained at lower temperatures, such as below or about 100° C. or lower. This may create a heat sink that can affect the temperature profile across the substrate. Temperature fluctuations may result in thickness variations of deposition across a substrate. The shields illustrated in FIGS. 7A-7C may include various emissivity patterns to reflect heat back upward to the support plate to at least partially protect against the thermal variation from radiative heat losses. The emissivity patterns include areas of different emissivity to reflect different amounts of heat back toward the support plate. Various techniques may be used to produce the varying levels of emissivity in the areas of each emissivity pattern. For example, different emissivity areas may include different materials, different surface textures (smooth, grooved, bumpy, etc.), different heights, different groove depths, different groove cross-sectional shapes, and/or other differences.

FIG. 7A illustrates a shield 700 having an inner emissivity section 705 and an outer emissivity section 710 that at least partially surrounds the inner emissivity section 705. For example, the inner emissivity section 705 may be an annular shape that extends about a central aperture 715 of the shield 700. The inner emissivity section 705 may be surrounded by an annular outer emissivity section 710. For example, the inner emissivity section 705 and outer emissivity section 710 may be coaxial, while in other embodiments, central axes of each of the emissivity sections may be offset from one another. It will be appreciated that other shapes of inner emissivity sections and/or outer emissivity sections 710 may be used, and that in some embodiments, at least a portion of the inner emissivity section 705 may extend to an outer periphery of the shield 700. The inner emissivity section 705 and outer emissivity section 710 may reflect different levels of heat back toward a support plate to control temperature of the support plate and/or a substrate positioned atop the support plate. While shown with two emissivity sections, shield 700 may include any number of emissivity sections. For example, the shield 700 may have greater than or about two emissivity sections, greater than or about 3 emissivity sections, greater than or about 4 emissivity sections, greater than or about 5 emissivity sections, greater than or about 6 emissivity sections, greater than or about 7 emissivity sections, greater than or about 8 emissivity sections, or more. FIG. 7B illustrates another embodiment of a shield 720 having multiple emissivity sections. Shield 720 may be similar to shield 700 and may include coaxial emissivity sections. For example, the shield 720 includes three annular emissivity sections. An inner emissivity section 725 may extend about a central aperture 740 and may be surrounded by a medial emissivity section 730 and an outer emissivity section 735. FIG. 7C illustrates another embodiment of a shield 750 having multiple emissivity sections. Shield 750 may include two elliptical emissivity sections 755 that are surrounded by a primary emissivity 760 section that encircles the elliptical emissivity sections 755 and a central aperture 765. In embodiments with three or more emissivity sections, all of the emissivity sections may have different emissivity rates, while in other embodiments, some or all emissivity sections that are not adjacent to one another may have a same emissivity rate. It will be appreciated that the emissivity patterns of the shields illustrated in FIGS. 7A-7C are merely intended as examples, and that other emissivity patterns exist in various embodiments. For example, emissivity patterns may include emissivity sections in the form linear strips, arcs, semi-circles, wedge shapes, and/or other polygonal or other shapes. Additionally, the emissivity patterns may be symmetrical or asymmetrical about the shield.

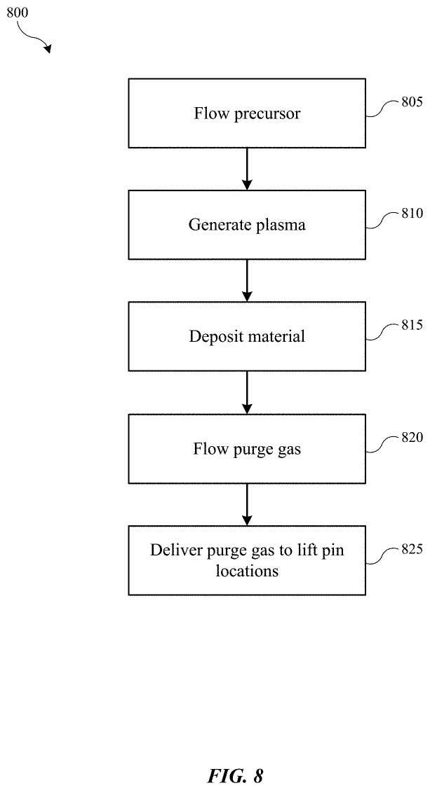

FIG. 8 shows operations of an exemplary method 800 of semiconductor processing according to some embodiments of the present technology. The method may be performed in a variety of processing chambers, including processing systems 200 and 300 and chambers 400, and 500 described above, which may include shields and purge baffles according to embodiments of the present technology, such as any shield and/or purge baffle discussed previously. Method 800 may include a number of optional operations, which may or may not be specifically associated with some embodiments of methods according to the present technology.

Method 800 may include a processing method that may include operations for forming a hardmask film or other deposition operations. The method may include optional operations prior to initiation of method 800, or the method may include additional operations. For example, method 800 may include operations performed in different orders than illustrated. In some embodiments, method 800 may include flowing one or more precursors into a processing chamber at operation 805. For example, the precursor may be flowed into a chamber, such as included in system 200, and may flow the precursor through one or more of a gasbox, a blocker plate, or a faceplate, prior to delivering the precursor into a processing region of the chamber. In some embodiments the precursor may be or include a carbon-containing precursor.

In some embodiments, a shield may be included in the system about the substrate support, such as about a shaft portion, where a substrate is positioned on a plate positioned above the shield. Any of the other characteristics of shields described previously may also be included. At operation 810, a plasma may be generated of the precursors within the processing region, such as by providing RF power to the faceplate to generate a plasma. Material formed in the plasma, such as a carbon-containing material, may be deposited on the substrate at operation 815.

At operation 820, a purge gas may be flowed into the processing chamber. For example, a purge gas source may deliver a purge gas, such as argon, helium, or hydrogen, into a purge baffle that directs the purge gas through a central aperture of a shield. The purge gas may be delivered to an underside of the semiconductor substrate to remove any deposition on the substrate at lift pin locations of the support plate at operation 825. For example, the purge gas may be diffused within a space formed between a bottom surface of the support plate and the top surface of the shield to direct the purge gas outward toward lift pin locations formed within the support plate. In some embodiments, one or more grooves formed within the shield may serve as flow channels that direct the purge gas to the lift pin locations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a chamber body comprising sidewalls and a base;
a substrate support extending through the base of the chamber body, wherein the substrate support comprises:
a support plate defining a plurality of lift pin locations; and
a shaft coupled with the support plate;
a shield coupled with the shaft of the substrate support and extending below a bottom surface of the support plate, the shield defining a central aperture that extends beyond an outer periphery of the shaft;
a purge baffle coupled with a bottom of the shield at a position that is beyond an outer periphery of the central aperture such that a space between the purge baffle and the outer periphery of the shaft is in fluid communication with a space between a top surface of the shield and the bottom surface of the support plate, the purge baffle extending along at least a portion of a length of the shaft; and
a purge gas source coupled with a bottom of the purge baffle.

2. The semiconductor processing system of claim 1, wherein:
a peripheral edge of the shield is positioned radially inward from the plurality of lift pin locations of the support plate.

3. The semiconductor processing system of claim 1, wherein:
a peripheral edge of the shield is positioned radially outward from the plurality of lift pin locations of the support plate;
the shield defines a plurality of apertures that extend at least partially through a thickness of the shield; and
each of the plurality of apertures is aligned with one of the plurality of lift pin locations.

4. The semiconductor processing system of claim 1, wherein:
the shield defines one or more grooves that extend between the central aperture and the plurality of lift pin locations.

5. The semiconductor processing system of claim 4, wherein:
a depth of the one or more grooves varies along a length of the one or more grooves.

6. The semiconductor processing system of claim 5, wherein:
the depth of the one or more grooves decreases in a radially outward direction.

7. The semiconductor processing system of claim 1, wherein:
the shield comprises a texture that provides an emissivity pattern for temperature modulation of a semiconductor substrate positioned atop the support plate.

8. A semiconductor processing system, comprising:
a substrate support comprising:
a support plate defining a plurality of lift pin locations; and
a shaft coupled with the support plate;
a shield having a body that defines a central aperture;
a purge baffle coupled with a bottom of the shield at a position that is beyond an outer periphery of the central aperture, the purge baffle extending along at least a portion of a length of the shaft, wherein a purge gas channel is formed in a space between the purge baffle, the shield, and the substrate support; and
a purge gas source coupled with a bottom of the purge baffle.

9. The semiconductor processing system of claim 8, wherein:
a peripheral edge of the shield is positioned radially inward from the plurality of lift pin locations of the support plate.

10. The semiconductor processing system of claim 8, wherein:
a peripheral edge of the shield is positioned radially outward from the lift pin locations of the support plate;
the shield defines a plurality of apertures that extend at least partially through a thickness of the shield; and
each of the plurality of apertures is aligned with one of the plurality of lift pin locations.

11. The semiconductor processing system of claim 8, wherein:
the shield defines one or more grooves that extend between the central aperture and the plurality of lift pin locations.

12. The semiconductor processing system of claim 11, wherein:
a depth of the one or more grooves varies along a length of the one or more grooves.

13. The semiconductor processing system of claim 12, wherein:
the depth of the one or more grooves decreases in a radially outward direction.

14. The semiconductor processing system of claim 8, wherein:
the shield comprises a texture that provides an emissivity pattern for temperature modulation of a semiconductor substrate positioned atop the support plate.

15. A method of semiconductor processing, comprising:
flowing a purge gas into a processing chamber, wherein the processing chamber comprises:
a substrate support comprising:
a support plate that supports a semiconductor substrate, the support plate defining a plurality of lift pin locations; and
a shaft coupled with the support plate;
a shield having a body that defines a central aperture;
a purge baffle coupled with a bottom of the shield at a position that is outside of the central aperture, the purge baffle extending along at least a portion of a length of the shaft, wherein a purge gas channel is formed in a space between the purge baffle, the shield, and the substrate support; and
a purge gas source coupled with a bottom of the purge baffle; and
delivering the purge gas to an underside of the semiconductor substrate at positions that are aligned with the plurality of lift pin locations via the purge gas channel.

16. The method of semiconductor processing of claim 15, wherein:
delivering the purge gas to the underside of the semiconductor substrate comprises passing the purge gas through one or more grooves that extend outward from the central aperture to the plurality of lift pin locations.

17. The method of semiconductor processing of claim 16, wherein:
a depth of the one or more grooves varies along a length of the one or more grooves.

18. The method of semiconductor processing of claim 17, wherein:
the depth of the one or more grooves decreases in a radially outward direction.

19. The method of semiconductor processing of claim 15, wherein:
a peripheral edge of the shield is positioned radially inward from the lift pin locations of the support plate; and
delivering the purge gas to the lift pin locations via the purge gas channel comprises passing the purge gas beyond the peripheral edge of the shield.

20. The method of semiconductor processing of claim 15, wherein:
the purge baffle is positioned about and spaced apart from an outer surface of the shaft and extends along at least a portion of the length of the shaft.
